(19) United States
(12) Patent Application Publication
(10) Pub. No.: US 2026/0026011 A1
(43) Pub. Date: Jan. 22, 2026

(54) SELF SELECTING MEMORY ELEMENT WITH FUNCTION OF SELF RECTIFYING AND LOGIC CIRCUIT IN MEMORY IMPLEMENTED USING THE SAME

(71) Applicant: IUCF-HYU (INDUSTRY-UNIVERSITY COOPERATION FOUNDATION HANYANG UNIVERSITY), Seoul (KR)

(72) Inventor: Jea Gun PARK, Seongnam-si (KR)

(73) Assignee: IUCF-HYU (INDUSTRY-UNIVERSITY COOPERATION FOUNDATION HANYANG UNIVERSITY), Seoul (KR)

(21) Appl. No.: 19/273,433

(22) Filed: Jul. 18, 2025

(30) Foreign Application Priority Data
Jul. 19, 2024 (KR) 10-2024-0095662

(51) Int. Cl. H10B 63/00

(52) U.S. Cl. CPC H10B 63/24

(57) ABSTRACT

Provided is a self-selecting memory with a dual functional layer that performs a dual function of self-rectification and self-selection by a dual layer structure of MₐGe₂Se_{c}/GeₓSe_{y} for CXL-based in-memory, and an in-memory logic circuit applied as a logic-in-memory using a diffusion mechanism of conductive M metal ions in a dual functional memory (DFM) of self-rectification and self-selection.

This work (outcome) is the result of the Samsung Future Technology Promotion Project, supported by Samsung Electronics Co., Ltd. in 2024. “[Samsung Future Technology Promotion Project] Self-rectifying selector-based memory with quad-level threshold voltage distribution using quasi-superlattice storage layer” [Project Number] SRFC-MA2402-01, [Research Period] Dec. 1, 2024˜Dec. 31, 2025

### CROSS-REFERENCE TO RELATED APPLICATION(S)

This application claims priority from and the benefit of Korean Patent Application No. 10-2024-0095662 filed on Jul. 19, 2024, which is hereby incorporated by reference in its entirety.

### BACKGROUND

### 1. Field

The present invention relates to a self-selecting memory, and more particularly, to a self-selecting memory device with a self-rectifying function and an in-memory logic circuit implemented as the self-selecting memory device.

### 2. Related Art

This work (outcome) is the result of the Samsung Future Technology Promotion Project, supported by Samsung Electronics Co., Ltd. in 2024. “[Samsung Future Technology Promotion Project] Self-rectifying selector-based memory with quad-level threshold voltage distribution using quasi-superlattice storage layer” [Project Number] SRFC-MA2402-01, [Research Period] Dec. 1, 2024˜Dec. 31, 2025

Compute-express-link (CXL) technology that may dramatically improve the memory size of central processing unit (CPU) and graphics processing unit (GPU) is currently manufactured based on a dynamic random-access-memory (DRAM) and supplied in the form of an expander.

At an initial stage, a cross-point array was proposed in which memory devices within a CXL were in a serial connection structure of ovonic threshold switching (OTS) selectors based on phase-change RAM (PCRAM) and OTS rather than DRAM.

Accordingly, a self-selecting memory (SSM) that performs a dual function of a selector and a memory in a single device has been considered as a promising candidate that may overcome various issues, such as high aspect ratio and thermal disturbance of three-dimensional (3D) X-point array (3DXP) for compute-express-link (CXL).

The conventional self-selecting memory device used Se_{y}(Si₁₅Te₃₄As₄₂Ge₉)_{1-y} as a resistive switching layer.

However, Se_{y}(Si₁₅Te₃₄As₄₂Ge₉)_{1-y} has a very complex material composition, making it difficult to control the composition ratio of a film during a deposition process and to ensure reliability.

Also, there was a large electroforming voltage of 4.2 V and an operating voltage was 3 to 4V, which was also very big.

Also, due to OTS mechanism-based threshold voltage switching, there was a chronic drift phenomenon.

Also, a high current (˜100 yA) flowed in both direction during set and reset programming, which caused very high power consumption when implementing a cross-point array.

Also, there were issues with the aspect ratio and thermal disturbance between adjacent cells.

Due to these issues, the conventional OTS-based self-selecting memory has not been applied as a new memory solution for 3DXP.

Patent Document 1 includes Korean Patent Registration No. 10-1375434 (registered on Mar. 11, 2014).

### SUMMARY

The present invention aims to provide a self-selecting memory device with a self-rectifying function supporting a logic in-memory with a diffusion mechanism of conductive M metal ions in a dual functional memory (DFM) for self-rectification and self-selection and double-layer stacking of MₐGe₂Se_{c}/GeₓSe_{y} for compute-express-link (CXL)-based in-memory.

Also, the present invention aims to provide an in-memory logic circuit that performs a logical operation through voltage application cycle adjustment of the self-selecting memory device.

Subjects to be solved by the present invention are not limited to the above-described subjects and may be variously expanded within the range that does not depart from the spirit and scope of the present invention.

An example embodiment provides a self-selecting memory device including a first electrode layer; an insulating layer deposited on top of the first electrode layer; a dual functional layer deposited on top of the insulating layer; and a second electrode layer deposited on top of the dual functional layer, wherein the dual functional layer is formed in a dual layer structure in which a storage layer, which is a GeSe compound layer doped with conductive metal ions deposited by sputtering, and a resistive switching layer, which is a GeSe compound layer, are stacked, and implements a self-rectifying function and a memory function by a threshold voltage shift phenomenon depending on the polarity when a negative voltage is applied to the first electrode layer.

The dual functional layer may be in a dual layer structure in which the storage layer formed as an MₐGe₂Se_{c} layer on the first electrode layer and the resistive switching layer formed as a GeₓSe_{y} layer between the storage layer and the insulating layer are stacked, and M may be a conductive metal.

a, b, and c denote weight ratios of M, Ge, and Se, respectively, a may be a real number between 10 and 30, b may be a real number between 10 and 30, and c may be a real number between 40 and 80, x and y denote weight ratios of Ge and Se, respectively, x may be a real number between 5 and 40, and y may be a real number between 60 and 95.

M may be at least one selected from a group consisting of conductive metal materials that include Cu, Al, Cr, Ni, Pt, Au, Ag, and Jr.

The sputtering power that targets the GeSe compound layer of M may be 30 to 60 watts.

The first electrode layer may further include a through-electrode that penetrates the insulating layer and contacts the dual functional layer.

A diffusion barrier film may be formed around the through-electrode to prevent a material of the insulating layer from diffusing into the insulating layer.

The dual functional layer may have a first threshold voltage at which a current flows by injecting M metal ions into the resistive switching layer to form a filament between the first electrode layer and the second electrode layer when a positive voltage is applied to the first electrode layer.

Due to the threshold voltage shift phenomenon that that the dual functional layer has a second threshold voltage greater than the first threshold voltage when a positive voltage is applied to the first electrode layer after the self-rectifying function is performed to block the current by applying a negative voltage to the first electrode layer to reinject the M metal ions into the storage layer, a memory function having a read window margin of a memory corresponding to a difference between the first threshold voltage and the second threshold voltage may be provided.

The filament generation speed of the M metal ions may be 10 to 40 ns during a write process, and may be 10 to 20 ns during a read process.

The dual functional layer may control a read window margin by adjusting at least one of the thickness of the storage layer and the resistive switching layer and the sputtering power.

An example embodiment provides an in-memory logic circuit configured to perform a logical operation by adjusting a voltage application cycle of at least one self-selecting memory device.

The logical operation may be at least one of AND, NAND, OR, NOR, NIMP, RIMP, RNIMP, X, Y, ˜X, ˜Y, True, False, XOR, and XNOR.

A self-selecting memory device with a self-rectifying function according to example embodiments may exhibit excellent endurance characteristics of 100 million cycles since a high current is not accompanied when a negative voltage is applied through the self-rectifying function and accordingly, thermal stress is reduced.

A self-selecting memory device with a self-rectifying function according to example embodiments may design a resistive switching layer in a dual layer structure of a dual functional material of MₐGe₂Se_{c} and GeₓSe_{y}(CuₐGe₂Se_{c}/GeₓSe_{y}), such that, when depositing germanium selenide that is a chalcogenide material doped with at least one metal M of Cu, Ag, Au, Al, and Ta, copper atoms are injected into a GeₓSe_{y} layer, and accordingly, an electroforming phenomenon does not absent, and, through this, the complexity of the peripheral circuit decreases during chip-level implementation.

In a self-selecting memory device with a self-rectifying function according to example embodiments, since threshold voltage switching is performed through generation and annihilation of filaments that includes M atoms and the annihilation speed of M filaments is very fast at 50 ns or less, the operation delay time according to atomic rearrangement does not occur, unlike the conventional OTS mechanism-based self-selecting memory device, and accordingly, no drift phenomenon occurs.

A self-selecting memory device with a self-rectifying function according to example embodiments may exhibit the fast operation speed of 40 ns using M atoms with very high mobility in a germanium selenide material.

A self-selecting memory device with a self-rectifying function according to example embodiments may design a resistive switching layer in a dual layer structure of MₐGe_{b}Se_{c}/GeₓSe_{y}, unlike the conventional self-selecting memory device, resulting in electroforming-free, drift-free, excellent endurance and reliability through a self-rectifying function, and low operating voltage characteristics, and may be used as a CXL-oriented memory device.

A self-selecting memory device with a self-rectifying function according to example embodiments may be implemented as an in-memory logic circuit having a logic-in-memory function capable of performing a logical operation inside CXL and may perform a CXL-based in-memory-computing function.

Effects of the present invention are not limited to the effects described above and other effects not described may be clearly understood by one of ordinary skill in the art from the following description.

### BRIEF DESCRIPTION OF THE FIGURES

Embodiments will be described in more detail with regard to the figures, wherein like reference numerals refer to like parts throughout the various figures unless otherwise specified, and wherein:

FIG. 1 is a scanning electron microscope (SEM) image of a self-selecting memory device with a self-rectifying function according to an example embodiment;

FIG. 2 is an enlarged view of a dual layer structure (2) of a dual functional material (DFM) layer of FIG. 1;

FIG. 3, (a), (b), (c), (d), and (e), illustrate the results of measuring the structure and composition characteristics of a self-selecting memory device with a self-rectifying function according to an example embodiment;

FIG. 4 is a graph showing IV characteristic curve of a self-selecting memory device with a self-rectifying function according to an example embodiment;

FIG. 5, (a), (b), (c), (d), (e), and (f), illustrate voltage current-characteristics during a write process and a read process according to an example embodiment;

FIG. 6, (a), (b), (c), (d), (e), and (f), illustrate the results of analyzing a mechanism of a threshold voltage shift phenomenon of a self-selecting memory device with a self-rectifying function according to an example embodiment;

FIG. 7, (a) and (b), are graphs showing the change in a read window margin (RWM) according to negative voltage magnitude according to an example embodiment;

FIG. 8, (a) and (b), are graphs showing double-sweep current-voltage characteristics for analyzing a threshold voltage switching operation mechanism of a self-selecting memory device with a self-rectifying function according to an example embodiment;

FIG. 9, (a) and (b), are graphs showing that a threshold voltage and an RWM may be changed by adjusting the concentration of Cu ions within a CuₐGe_{b}Se_{c} layer of a self-selecting memory device with a self-rectifying function according to an example embodiment;

FIG. 10, (a), (b), and (c), are graphs showing current-voltage characteristics according to a compliance current (CC) level and a cell size according to an example embodiment;

FIG. 11, (a), (b), and (c), are graphs showing the reliability of a self-selecting memory device with a self-rectifying function in a high temperature environment (85° C.) according to an example embodiment;

FIG. 12, (a), (b), and (c), are graphs showing drift-free characteristics and excellent endurance characteristics of a self-selecting memory device with a self-rectifying function according to an example embodiment;

FIG. 13, (a) and (b), are graphs showing the cycle-to-cycle variation and the device-to-device variation of a threshold voltage (set state and reset state) of a self-selecting memory device with a self-rectifying function according to an example embodiment;

FIGS. 14A to 14C are logical operation time charts applied with a sequential logic scheme implemented by logic circuits in a memory generated using a self-selecting memory device with a self-rectifying function according to an example embodiment; and

FIG. 15, (a), (b), (c), (d), and (e), illustrate the results of implementing a full-adder using three self-selecting memory devices each with a self-rectifying function according to an example embodiment.

### DETAILED DESCRIPTION

The specific structural or functional descriptions of example embodiments according to the concept of the present invention described herein are merely intended for the purpose of describing the example embodiments according to the concept of the present invention, and the example embodiments according to the concept of the present invention may be implemented in various forms and are not construed as limited to the example embodiments described herein.

Various modifications and various forms may be made to the example embodiments according to the concept of the present invention and thus, the example embodiments are illustrated in the drawings and described in detail through the present specification. However, it should be understood that the example embodiments according to the concept of the present invention are not construed as being limited to specific implementations and should be understood to include all changes, equivalents, and replacements within the idea and the technical scope of the present invention.

Although terms of “first,” “second,” and the like are used to explain various components, the components are not limited to such terms. These terms are used only to distinguish one component from another component. For example, a first component may be referred to as a second component, or similarly, the second component may be referred to as the first component without departing from the scope according to the concept of the present invention.

When it is mentioned that one component is “connected” or “accessed” to another component, it may be understood that the one component is directly connected or accessed to the other component or that still other component is interposed between the two components. In addition, when it is described that one component is “directly connected” or “directly accessed” to another component, it should be understood that still other component is absent therebetween. Likewise, expressions describing relationships between components, for example, “between” and “immediately between” and “immediately adjacent to” may also be construed as described in the foregoing.

The terminology used herein is for the purpose of describing particular example embodiments only and is not to be limiting of the present invention. As used herein, the singular forms “a,” “an,” and “the” are intended to include the plural forms as well, unless the context clearly indicates otherwise. It will be further understood that the terms “comprises/includes” or “has,” when used in this specification, specify the presence of stated features, integers, stages, operations, components, parts, or combinations thereof, but do not preclude the presence or addition of one or more other features, integers, stages, operations, components, parts, or combinations thereof.

Unless otherwise defined herein, all terms used herein including technical or scientific terms have the same meanings as those generally understood by one of ordinary skill in the art. Terms defined in dictionaries generally used should be construed to have meanings matching contextual meanings in the related art, and are not to be construed as an ideal or excessively formal meaning unless otherwise defined herein.

Hereinafter, example embodiments will be described in detail with reference to the accompanying drawings. However, the scope of the claims is not limited to or restricted by the example embodiments. Like reference numerals presented in the respective drawings refer to like components throughout.

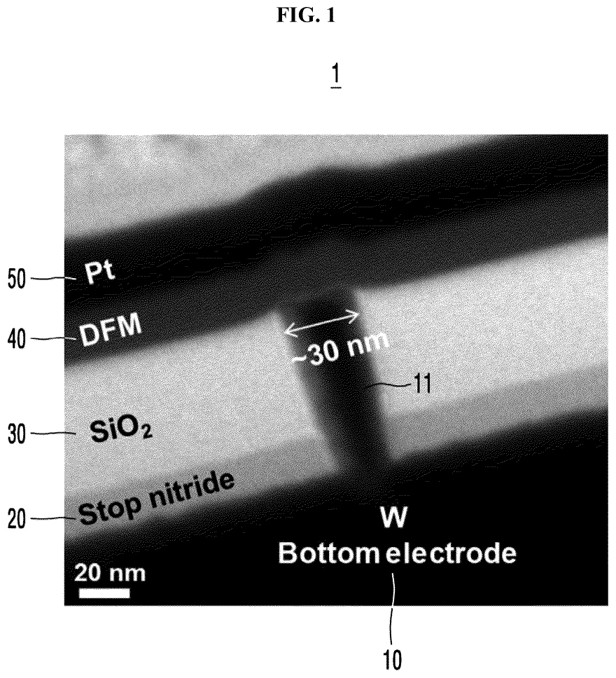

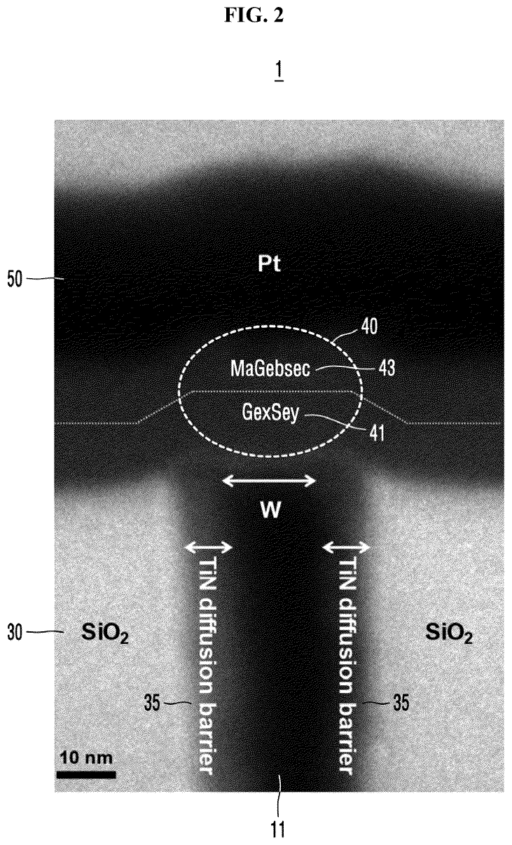

FIG. 1 is a scanning electron microscope (SEM) image of a self-selecting memory device with a self-rectifying function according to an example embodiment, and FIG. 2 is an enlarged view of a dual layer structure (2) of a dual functional material (DFM) layer of FIG. 1.

Referring to FIGS. 1 and 2, the self-selecting memory device 1 with the self-rectifying function may include a first electrode layer 10, an insulating layer 20 deposited on the first electrode layer, a dual functional layer 40 deposited on top of the insulating layer 20, and a second electrode layer 50 deposited on top of the dual functional layer 40.

The dual functional layer 40 may be formed in a dual layer structure in which a storage layer, which is a GeSe compound layer doped with conductive metal ions deposited by sputtering, and a resistive switching layer, which is a GeSe compound layer, are stacked.

The dual functional layer 40 in the above structure may implement the self-rectifying function and a memory function by a threshold voltage shift phenomenon depending on the polarity when a negative voltage is applied to the first electrode 50.

The dual functional layer 40 may be in a dual layer structure in which a storage layer 41 formed as an MₐGe₂Se_{c} layer on the first electrode layer 10 and a resistive switching layer 43 formed as a GeₓSe_{y} layer between the storage layer 41 and an insulating layer 30, and M may be a conductive metal or conductive metal ions.

a, b, and c denote weight ratios of M, Ge, and Se, respectively. Here, a may be a real number between 10 and 30, b may be a real number between 10 and 30, and c may be a real number between 40 and 80.

x and y denote weight ratios of Ge and Se, respectively. Here, x may be a real number between 5 and 40, and y may be a real number between 60 and 95.

M may be at least one selected from a group of conductive metal materials that include Cu, Al, Cr, Ni, Pt, Au, Ag, and Jr.

The sputtering power that targets the GeSe compound layer of M may be 30 to 60 watts.

The first electrode layer 10 may further include a through-electrode 11 that penetrates the insulating layer 30 and contacts the dual functional layer 40.

A diffusion barrier film 35 may be formed around the through-electrode 11 to prevent a material of the insulating layer 30 from diffusing into the insulating layer 30.

The dual functional layer 40 has a first threshold voltage at which a current flows by injecting M metal ions into the resistive switching layer 43 to form a filament between the first electrode layer 10 and the second electrode layer 50 when a positive voltage is applied to the first electrode layer 10.

Then, when a negative voltage is applied to the first electrode layer 10, the self-rectifying function is performed to block the current by reinjecting the M metal ions into the storage layer 41. Then, when a positive voltage is applied to the first electrode layer 10, a threshold voltage shift phenomenon occurs that the dual functional layer 40 has a second threshold voltage greater than the first threshold voltage. Therefore, the self-selecting memory device 1 according to an example embodiment may provide a memory function having a read window margin of a memory corresponding to a difference between the first threshold voltage and the second threshold voltage.

Here, the filament generation speed of the M metal ions may be 10 to 40 ns during a write process, and may be 10 to 20 ns during a read process.

The dual functional layer 40 may control a read window margin by adjusting at least one of the thickness of the storage layer and the resistive switching layer and the sputtering power.

Example embodiment provide an in-memory logic circuit configured to perform a logical operation by adjusting a voltage application cycle of at least one self-selecting memory device.

The logical operation may be at least one of AND, NAND, OR, NOR, NIMP, RIMP, RNIMP, X, Y, ˜X, ˜Y, True, False, XOR, and XNOR.

### Embodiment

Si₃N₄ with the thickness of 20 nm and SiO₂ with the thickness of 50 nm were sequentially deposited on a 12-inch W wafer through chemical vapor deposition (CVD), and nanoholes with the diameter of 30 nm were patterned using photolithography and dry etching.

A TiN diffusion barrier and a W film were sequentially deposited on the nanoholes, a plug-typed W lower electrode with the thickness of 70 nm was fabricated through a chemical mechanical planarization (CMP) process.

Then, to fabricate an active cell area of a self-selecting memory device with a self-rectifying function (self-rectifying self-selecting memory (SR-SSM), 200 μL of photoresist (AZ5214E) was spin-coated at 5000 rpm for 30 seconds on a plug-typed W-patterned coupon wafer with the size of 1.0×1.5 cm² and then, soft-baked at₁₂0E for 100 seconds.

Also, a 60×60 μm² patterned photomask was aligned on the plug-typed W-pattern wafer, and exposed to ultraviolet (UV) light with beam intensity of 20 mW/cm² for 4 seconds. The exposed photoresist was developed using a developer (AZ300MIF) for 70 seconds.

An 10 nm-thick Ge₃₀Se₇₀ resistive switching layer was deposited on the plug-typed W lower electrode with the size of 60×60 μm² by sputtering a GeSe target at RF power of 30 W under Ar flow of 40 sccm.

An 10 nm-thick Cu₂₆Ge₂₄Se₅₀ storage layer was deposited by co-sputtering GeSe target at RF power of 30 W and Cu target at RF power of 40 W under Ar flow of 40 sccm.

A 30 nm-thick Pt upper electrode was sputtered using a Pt target at direct current (DC) power of 30 W under Ar flow of 30 sccm. Finally, the SR-SSM was patterned through a lift-off process using acetone, methanol, and DI water cleaning. Through this, the SR-SSM was fabricated entirely with a vertical structure of the W lower electrode, the Ge₃₀Se₇₀ resistive switching layer, the Cu₂₆Ge₂₄Se₅₀ storage layer, and the Pt upper electrode, with the diameter of 30 nm.

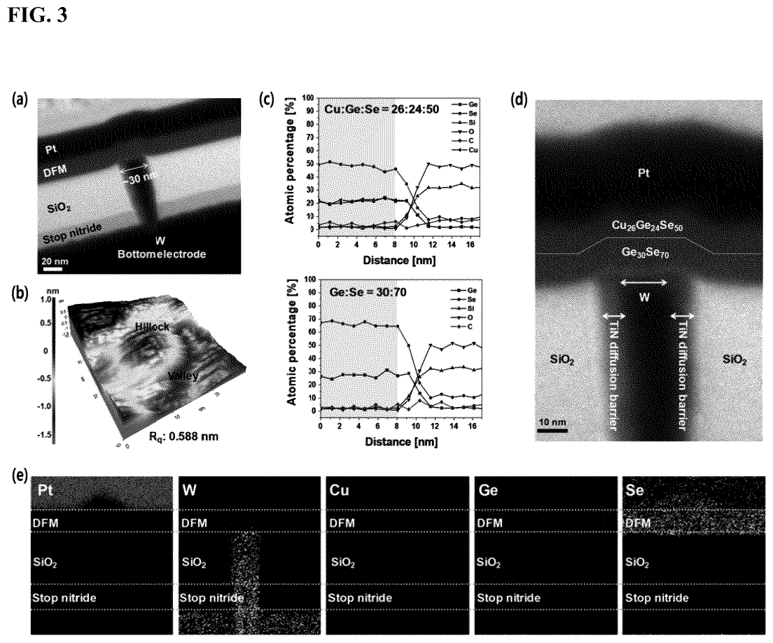

FIG. 3, (a), (b), (c), (d), and (e), illustrate the results of measuring the structure and composition characteristics of a self-selecting memory device with a self-rectifying function according to an example embodiment.

As shown in (a) to (c) of FIG. 3, the self-selecting memory device 1 with the self-rectifying function has a cell size of 30 nm×30 nm. Here, 10 nm-thick CuGeSe and 10 nm-thick GeSe were used as resistive switching layers. Here, tungsten (W) was used for a lower electrode and Pt was used for an upper electrode.

As shown in (d) of FIG. 3, a precise composition ratio of Cu₂₆Ge₂₄Se₅₀ and Ge₃₀Se₇₀ was secured by adjusting the radio frequency (RF) power of Cu and GeSe targets during a sputtering process.

As shown in (e) of FIG. 3, each of atoms (Pt, W, Ge, Se) is distributed in each area. However, in the case of Cu, it can be confirmed that Cu is injected and distributed up to a Ge₃₀Se₇₀ layer due to the strong energy during sputtering. An electroforming phenomenon may be eliminated by copper atoms injected in this way.

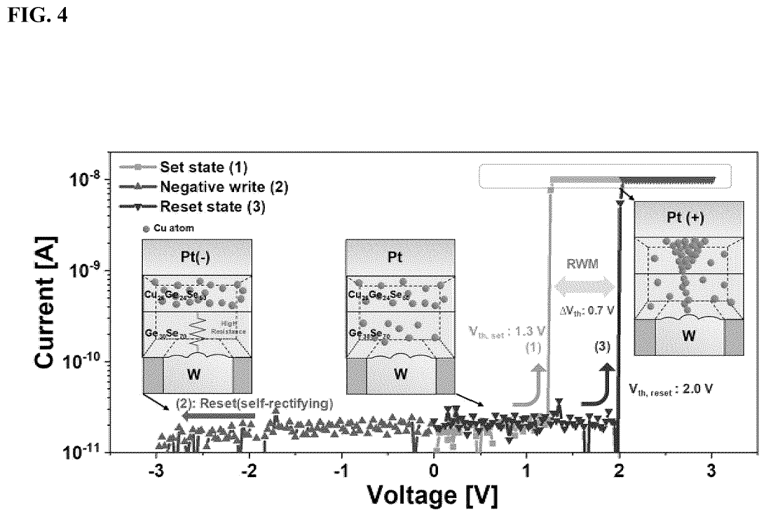

FIG. 4 is a graph showing IV characteristic curve of the self-selecting memory device 1 with the self-rectifying function according to an example embodiment.

As shown in FIG. 4, when a positive voltage of up to 3V was applied to a Pt electrode layer in an initial state, threshold voltage switching occurred at around 1.3 V. Then, when a negative voltage of up to −3 V was applied, a rectifying function was exhibited in which no current flowed. Then, when a positive voltage of up to 3 V was applied again, threshold voltage switching occurred at around 2.0 V. If a read process is performed around 1.5 V, it can be read that it is in a set state and a reset state. Using this threshold voltage shift phenomenon, a memory function may be implemented. A read window margin (RWM) during the read function was 0.7 V corresponding to a difference between 1.3 V and 2.0 V.

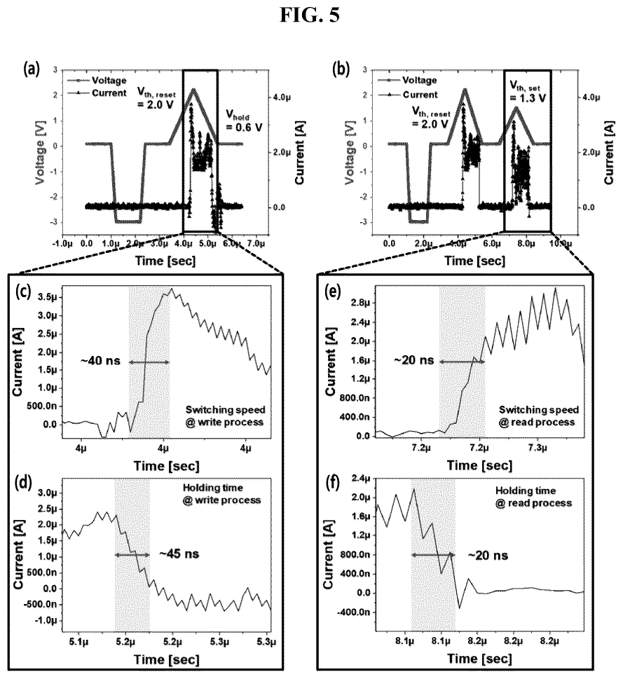

FIG. 5, (a), (b), (c), (d), (e), and (f), illustrate voltage current-characteristics during a write process and a read process according to an example embodiment.

FIG. 5 shows generation and annihilation speeds of copper atom filaments in the write process and the read process of the self-selecting memory device with the self-rectifying function.

As shown in FIG. 5, it can be seen that this fast switching speed is due to copper having verify fast mobility within a germanium selenide material.

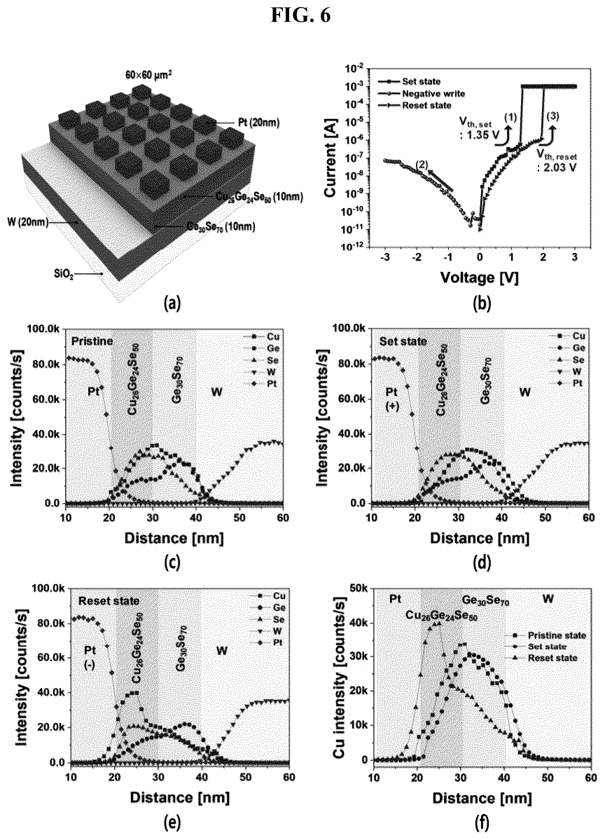

FIG. 6, (a), (b), (c), (d), (e), and (f), illustrate the results of analyzing a mechanism of a threshold voltage shift phenomenon of a self-selecting memory device with a self-rectifying function according to an example embodiment.

As shown in (a) of FIG. 6, a large-size self-selecting memory device with a self-rectifying function with a cell size of 60 μm×60 μm was fabricated on a SiO₂ substrate. Here, a 20 nm-thick W lower electrode, a 10 nm-thick Cu₂₆Ge₂₄Se₅₀, a 10 nm-thick Ge₃₀Se₇₀, and a 20 nm-thick Pt electrode were deposited.

(b) of FIG. 6 shows the fabricated self-selecting memory current-voltage characteristics with the self-rectifying function with the cell size of 60 μm×60 μm.

Unlike the self-selecting memory with the self-rectifying function with the cell size of 30 nm×30 nm as shown in (a) to (c) of FIG. 3, it can be confirmed that leakage current increased according to an increase in the cell size. However, due to the generation and annihilation operation of copper atom filaments, it can be seen that the threshold voltage did not greatly change in the set state and the reset state.

As shown in (c) to (e) of FIG. 6, a total of three samples were prepared and analyzed using a time-of-flight secondary ion mass spectrometer in an initial state (state in which no voltage was applied), a set state (state in which 3V was applied), and a reset state (state in which −3 V was applied) to determine how each ion was distributed depending on the state. The analysis results show that the distribution of Pt, Ge, Se, W did not change significantly depending on the bias polarity history. However, as shown in (f) of FIG. 6, a clear difference was observed in the case of Cu. In the initial state, Cu ions were mainly distributed at the boundary between the Cu₂₆Ge₂₄Se₅₀ layer and the Ge₃₀Se₇₀ layer.

However, in the set state, it was found that Cu ions migrated due to the applied positive voltage and were mainly distributed within the Ge₃₀Se₇₀ layer.

In the reset state, it was confirmed that Cu ions migrated toward the upper electrode due to the negative voltage and were mainly distributed within the Cu₂₆Ge₂₄Se₅₀ layer. It is confirmed that Cu ions migrate within the resistive switching layer according to the applied bias polarity history, changing the overall device resistance and, through this, causing a threshold voltage shift phenomenon.

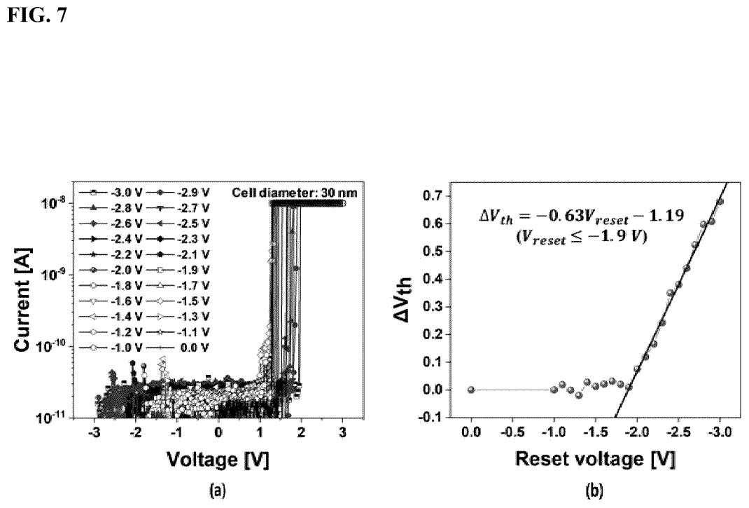

FIG. 7, (a) and (b), are graphs showing the change in a read window margin (RWM) according to negative voltage magnitude according to an example embodiment.

(a) and (b) of FIG. 7 show the change in RWM according to the negative voltage magnitude. When the negative voltage magnitude was increased from −1.0 to −3.0 in units of 0.1 V, there was no change in the RWM up to about −1.9 V. However, it was confirmed that RWM linearly increased from −1.9 V up to −3.0 V This indicates that up to the −1.9 V operating voltage range, Cu ions injected into the Ge₃₀Se₇₀ layer are unable to significantly migrate toward an upper electrode, so there is no change in the RWM, but in a voltage area higher than this, a sufficient amount of Cu ions are injected into the Cu₂₆Ge₂₄Se₅₀ layer, so the RWM linearly increases.

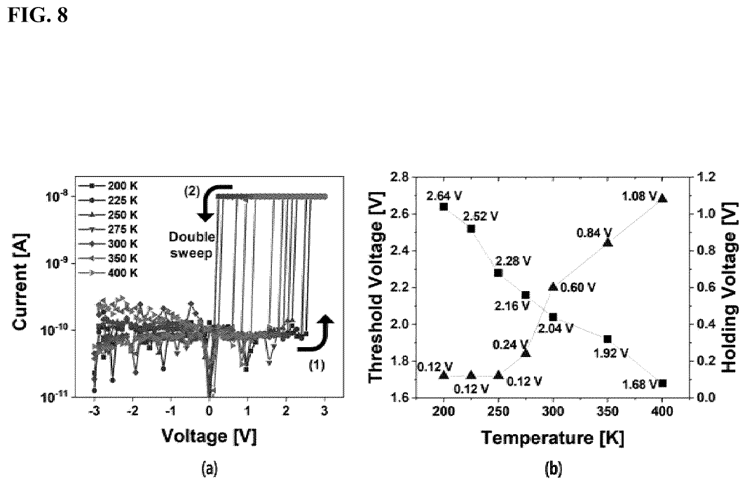

FIG. 8, (a) and (b), are graphs showing double-sweep current-voltage characteristics for analyzing a threshold voltage switching operation mechanism of a self-selecting memory device with a self-rectifying function according to an example embodiment.

To demonstrate a copper atom filament-based threshold voltage switching operation mechanism, the current-voltage characteristics were measured at cryogenic temperature ranging from −100 K to high temperature up to 400 K.

In an extremely low temperature environment, a threshold voltage was about 2.64 V, and a holding voltage (voltage at which filament breaks) was about 0.12 V As the temperature increased up to the high temperature range, the threshold voltage decreased to 1.68 V and the holding voltage increased to 1.08 V This shows that in a low temperature environment, copper diffusion does not occur well, so the voltage for threshold voltage switching increases, whereas the voltage at which the filament generated once breaks on its own converges to 0 V Also, this shows that in a high temperature environment, unlike in the low temperature environment, the diffusion of copper atoms increases, so threshold voltage switching is performed even at low voltage and the filament generated once also breaks even at high voltage.

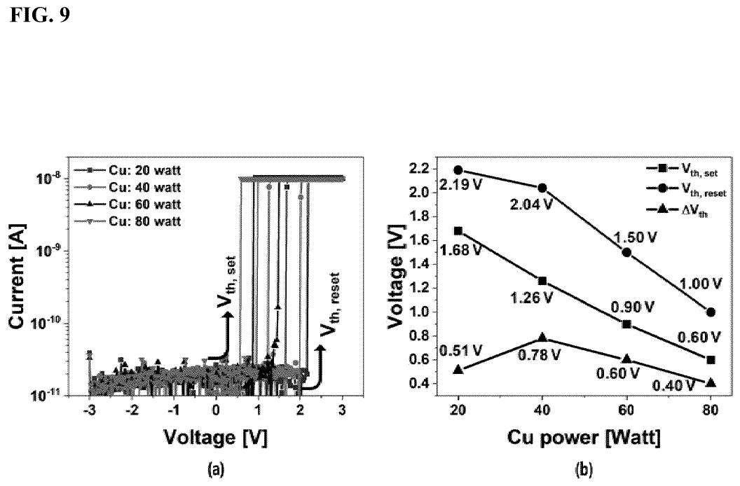

FIG. 9, (a) and (b), are graphs showing that a threshold voltage and an RWM may be changed by adjusting the concentration of Cu ions within a CuₐGe_{b}Se_{c} layer of a self-selecting memory device with a self-rectifying function according to an example embodiment.

In the case of the Cu₂₆Ge₂₄Se₅₀ layer, Cu was deposited at RF power 40 W. In the case of reducing the Cu RF power to 20 W or increasing the same to 60 and 80 W, it can be confirmed that the threshold voltage decreases in both the set state and the reset state according to the increase in Cu RF power. This indicates that, as the Cu RF power increases, an amount of Cu ions injected into the Ge₃₀Se₇₀ layer increases, which reduces the resistance of the entire device, thereby reducing the threshold voltage. As the threshold voltage decreased in both the set state and the reset state, an absolute RWM value also changed and the Cu₂₆Ge₂₄Se₅₀ layer with the RF power of 40 W exhibited the most excellent characteristics at the level of 0.78 V.

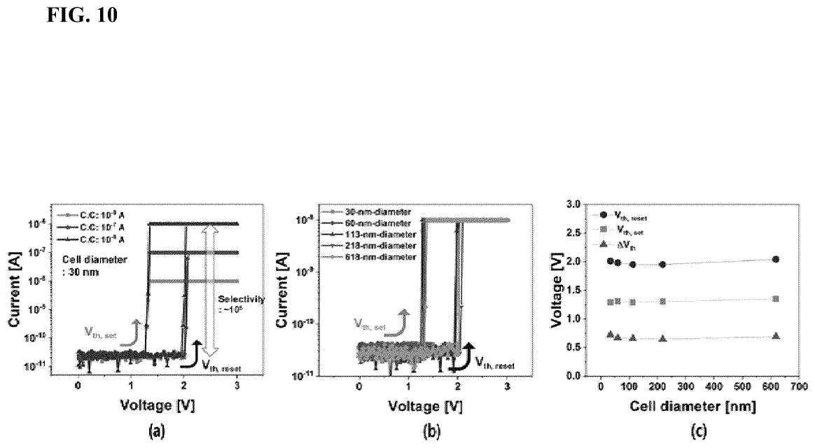

FIG. 10, (a), (b), and (c), are graphs showing current-voltage characteristics according to a compliance current (CC) level and a cell size according to an example embodiment.

The current-voltage characteristics according to the compliance current level and the cell size are shown. (a) of FIG. 10 shows that, when increasing the compliance current level from 10 nAto 1 μA, there is no change in the threshold voltage and accordingly, the RWM also remains constant. It is confirmed that the self-selecting memory device with the self-rectifying function with the cell size of 30 nm×30 nm exhibits the high selectivity of up to about 105.

(b) and (c) of FIG. 10 show the current-voltage characteristics according to the change in the cell size. The self-selecting memory device with the self-rectifying function according to an example embodiment performs a threshold voltage switching operation based on cupper atom filament, so it is confirmed that neither leakage current nor threshold voltage significantly changes up to the cell size of about 618 nm×618 nm. Therefore, it is confirmed that the change in the RWM is consistent. This indicates that the self-selecting memory device with the self-rectifying function operates with threshold voltage switching using nanoscale copper filaments.

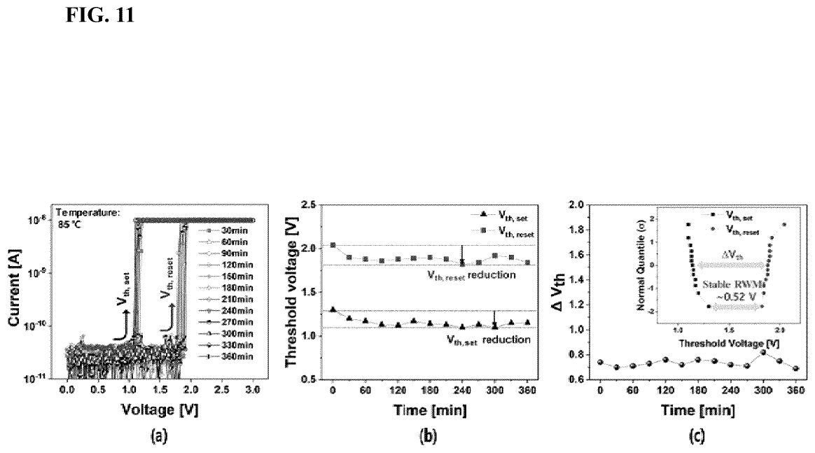

FIG. 11, (a), (b), and (c), are graphs showing the reliability of a self-selecting memory device with a self-rectifying function in a high temperature environment (85° C.) according to an example embodiment.

As shown in (a) of FIG. 11, current-voltage characteristics were measured at intervals of 30 minutes for a total of 6 hours in a high temperature environment. As shown in (b) of FIG. 11, the threshold voltage decreased in both the set state and the reset state by about 0.2 V. This may indicate that copper ions diffused in the high temperature environment and were injected into the Ge₃₀Se₇₀ layer. However, as shown in (c) of FIG. 11, the threshold voltage decreased in both the set and the reset state, so there was no significant change in the RWM.

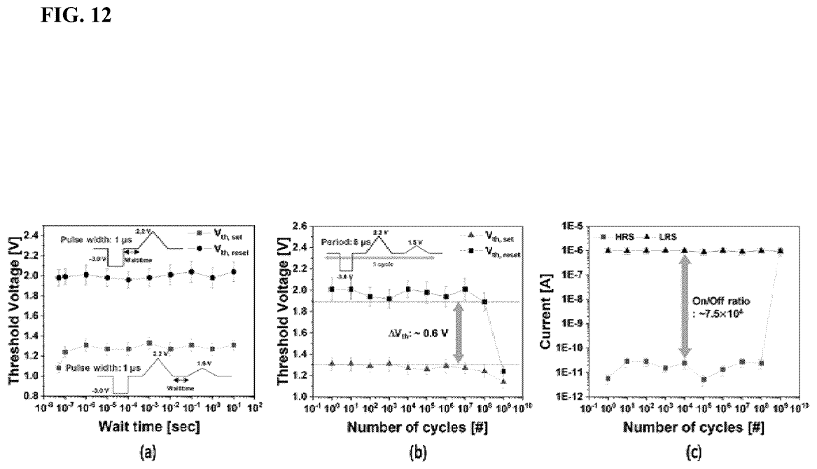

FIG. 12, (a), (b), and (c), are graphs showing drift-free characteristics and excellent endurance characteristics of a self-selecting memory device with a self-rectifying function according to an example embodiment.

As shown in (a) of FIG. 12, a delay time from the set state and the reset state to a subsequent switching operation is defined as a wait time, and the magnitude of threshold voltage according to this time interval was measured. The measurement results show that the threshold voltage remains constant in the set state and the reset state without change after the wait time of 50 ns. This confirms that the self-selecting memory device with the self-rectifying function has the decay time of less than 50 ns for copper filaments, so there is no change in the threshold voltage, that is, no drift phenomenon in a subsequent operation.

(b) and (c) of FIG. 12 show excellent endurance characteristics of more than 100 million cycles (10⁸) of the self-selecting memory device with the self-rectifying function. Typically, devices that operate with atom-based filaments such as silver (Ag) or copper (Cu) do not have good endurance. However, the present invention incorporates the self-rectifying function such that high current does not flow during reset programming, thereby reducing electrically induced thermal stress and improving the endurance of the entire device.

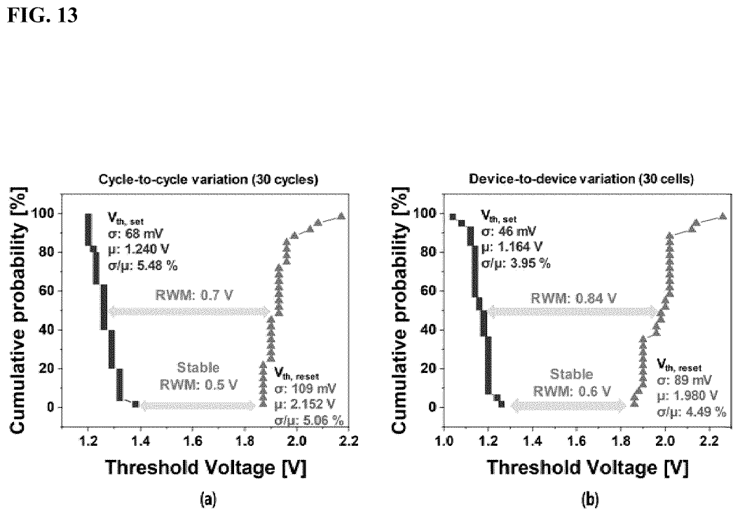

FIG. 13, (a) and (b), are graphs showing the cycle-to-cycle variation and the device-to-device variation of a threshold voltage (set state and reset state) of a self-selecting memory device with a self-rectifying function according to an example embodiment.

As shown in FIG. 13, it can be seen that the electrically induced thermal stress may be reduced through the self-rectifying function, thereby showing the overall low variation of about 5% in the cycle-to-cycle variation and the device-to-device variation.

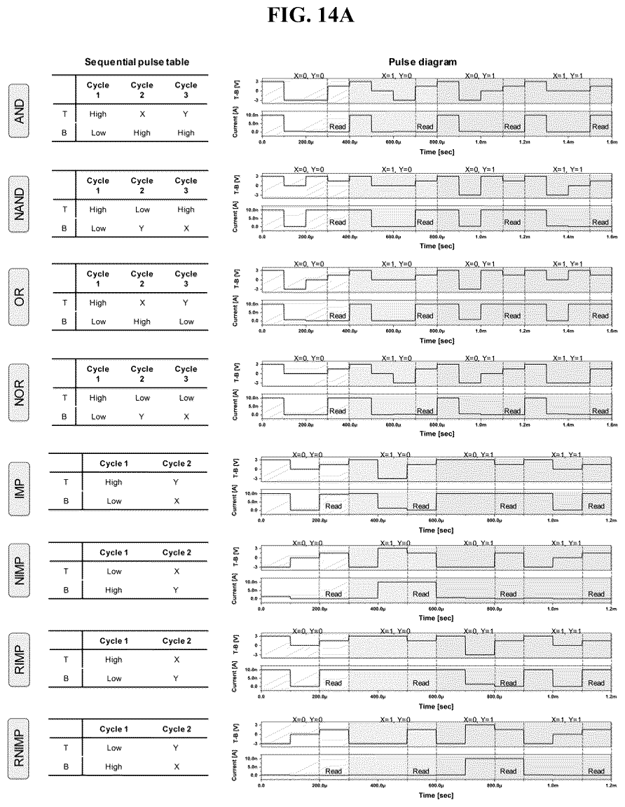

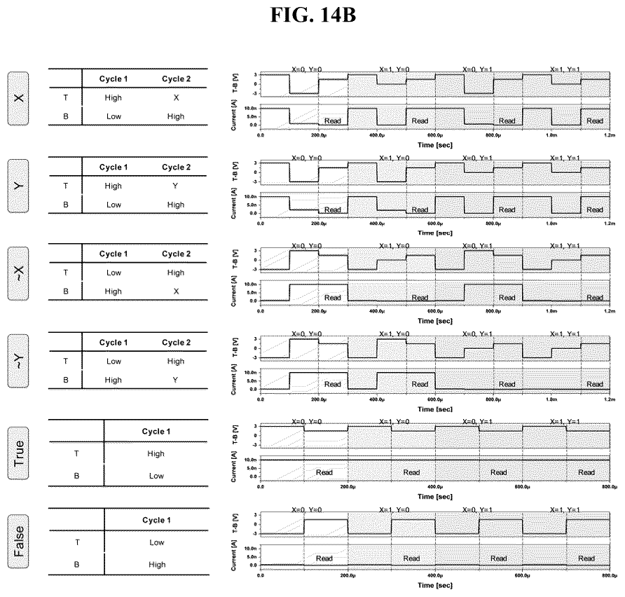

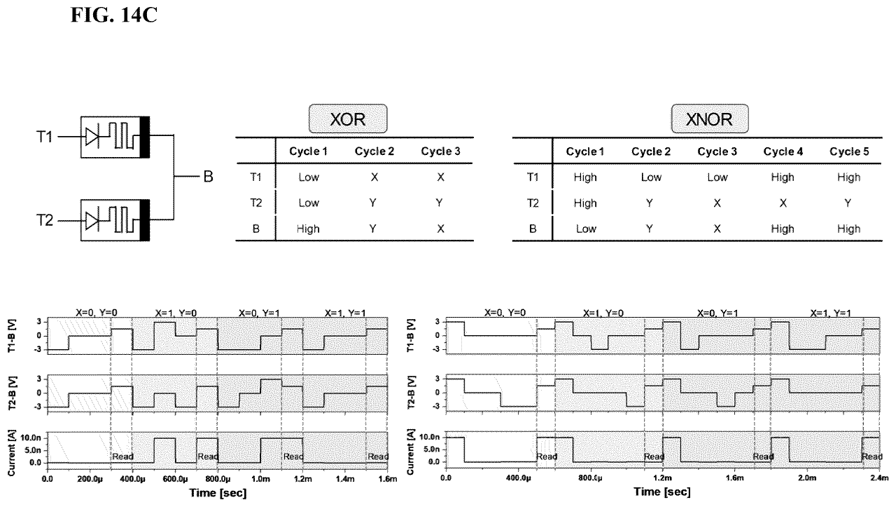

FIGS. 14A to 14C are logical operation time charts applied with a sequential logic scheme implemented by logic circuits in a memory generated using a self-selecting memory device with a self-rectifying function according to an example embodiment.

This is the result of implementing 16 Boolean logic gates by applying a sequential logic scheme using the self-selecting memory device with the self-rectifying function. 14 Boolean logic gates (AND, NAND, OR, NOR, IMP, NIMP, RIMP, RNIMP, X, Y, not X, not Y, True, and False) are implemented using a single self-selecting memory device with the self-rectifying function.

Exclusive OR (XOR) and exclusive NOR (XNOR) gates are implemented using two self-selecting memory devices each with the self-rectifying function.

Expressions “high” and “low” in each cycle are +3 V and 0 V, and X and Y are operands of Boolean logic in the form of voltage.

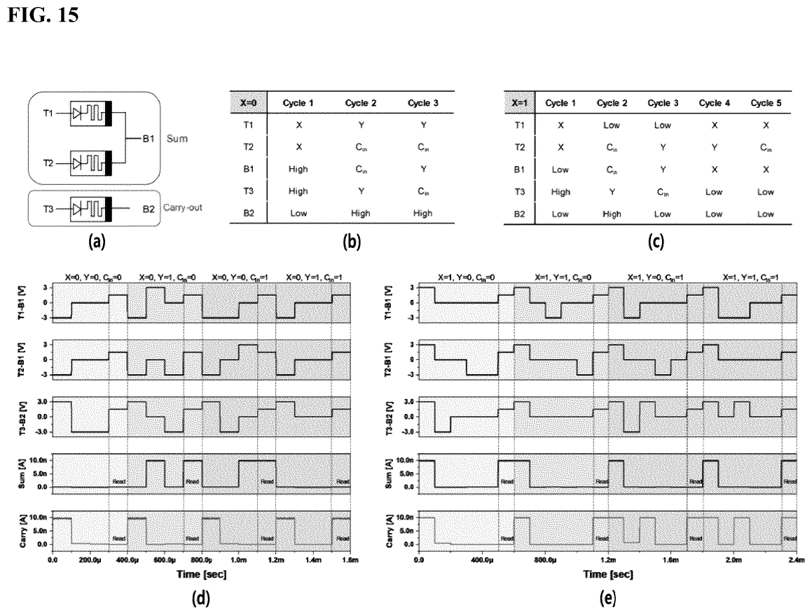

FIG. 15, (a), (b), (c), (d), and (e), illustrate the results of implementing a full-adder using three self-selecting memory devices each with a self-rectifying function according to an example embodiment.

As in FIG. 15, expressions “high” and “low” in each cycle are +3 V and 0 V, X, Y, and Cin are operands of Boolean logic in the form of voltage.

Although the example embodiments are described with reference to the accompanying drawings, it will be apparent to one of ordinary skill in the art that various alterations and modifications in forms and details may be made in these example embodiments without departing from the spirit and scope of the claims and their equivalents. For example, suitable results may be achieved if the described techniques are performed in different order, and/or if components in a described system, architecture, device, or circuit are combined in a different manner, and/or replaced or supplemented by other components or their equivalents.

Therefore, other implementations, other example embodiments, and equivalents of the claims are to be construed as being included in the claims.

What is claimed is:

1. A self-selecting memory device comprising:
a first electrode layer;
an insulating layer deposited on top of the first electrode layer;
a dual functional layer deposited on top of the insulating layer; and
a second electrode layer deposited on top of the dual functional layer,
wherein the dual functional layer is formed in a dual layer structure in which a storage layer, which is a GeSe compound layer doped with conductive metal ions deposited by sputtering, and a resistive switching layer, which is a GeSe compound layer, are stacked, and implements a self-rectifying function and a memory function by a threshold voltage shift phenomenon depending on the polarity when a negative voltage is applied to the first electrode layer.

2. The self-selecting memory device of claim 1, wherein:
the dual functional layer is in a dual layer structure in which the storage layer formed as an MₐGe₂Se_{c} layer on the first electrode layer and the resistive switching layer formed as a GeₓSe_{y} layer between the storage layer and the insulating layer are stacked, and
M is a conductive metal.

3. The self-selecting memory device of claim 2, wherein:
a, b, and c denote weight ratios of M, Ge, and Se, respectively,
a is a real number between 10 and 30, b is a real number between 10 and 30, and c is a real number between 40 and 80,
x and y denote weight ratios of Ge and Se, respectively,
x is a real number between 5 and 40, and y is a real number between 60 and 95.

4. The self-selecting memory device of claim 2, wherein M is at least one selected from a group consisting of conductive metal materials that include Cu, Al, Cr, Ni, Pt, Au, Ag, and Jr.

5. The self-selecting memory device of claim 2, wherein the sputtering power that targets the GeSe compound layer of M is 30 to 60 watts.

6. The self-selecting memory device of claim 1, wherein the first electrode layer further includes a through-electrode that penetrates the insulating layer and contacts the dual functional layer.

7. The self-selecting memory device of claim 6, wherein a diffusion barrier film is formed around the through-electrode to prevent a material of the insulating layer from diffusing into the insulating layer.

8. The self-selecting memory device of claim 1, wherein:
the dual functional layer has a first threshold voltage at which a current flows by injecting M metal ions into the resistive switching layer to form a filament between the first electrode layer and the second electrode layer when a positive voltage is applied to the first electrode layer, and
due to the threshold voltage shift phenomenon that that the dual functional layer has a second threshold voltage greater than the first threshold voltage when a positive voltage is applied to the first electrode layer after the self-rectifying function is performed to block the current by applying a negative voltage to the first electrode layer to reinject the M metal ions into the storage layer, a memory function having a read window margin of a memory corresponding to a difference between the first threshold voltage and the second threshold voltage is provided.

9. The self-selecting memory device of claim 8, wherein the filament generation speed of the M metal ions is 10 to 40 ns during a write process, and 10 to 20 ns during a read process.

10. The self-selecting memory device of claim 1, wherein the dual functional layer controls a read window margin by adjusting at least one of the thickness of the storage layer and the resistive switching layer and the sputtering power.

11. An in-memory logic circuit configured to perform a logical operation by adjusting a voltage application cycle of the self-selecting memory device through alone or combination of two or more self-selecting memory devices of claim 1.

12. The in-memory logic circuit of claim 11, wherein the logical operation is at least one of AND, NAND, OR, NOR, NIMP, RIMP, RNIMP, X, Y, ˜X, ˜Y, True, False, XOR, and XNOR.
